(19) United States
(12) Patent Application Publication
(10) Pub. No.: US 2015/0204698 A1
(43) Pub. Date: Jul. 23, 2015

(54) LOCATION CONTROL ENCODING METHOD IN LOCATION CONTROL ENCODING DEVICE

(71) Applicant: Sang Yong LEE, Siheung-si, Gyeonggi-do (KR)

(72) Inventor: Sang Yong Lee, Gyeonggi-do (KR)

(21) Appl. No.: 14/414,574

(22) PCT Filed: Jul. 8, 2013
(86) PCT No.: PCT/KR2013/006034

§ 371 Date: Jan. 13, 2015

(30) Foreign Application Priority Data
Jul. 13, 2012 (KR) 10-2012-0076820

(51) Int. Cl. G01D 9/02; G01D 5/14; G01D 5/26; H03M 7/12

(52) U.S. Cl. CPC G01D 9/02; H03M 7/12; G01D 5/14; G01D 5/26

(57) ABSTRACT

The present invention relates to a programmable location control encoder, wherein the encoder has a new function of combining a sequential control function to conventional rotary encoders. The present invention comprises: a rotary disk having an absolute location code indicative of each location, that is, an address code formed by a combination of binary numbers; an optical sensor for detecting said binary address code; a signal amplification unit for amplifying an output signal of the optical sensor; and a control circuit board for outputting a digital signal by using a signal outputted from the signal amplification unit. According to the present invention, it is possible to convert a partition angle or a location control code by configuring a software resolution, and to maximize work efficiency by combining a sequential control function to conventional rotary encoders.

### TECHNICAL FIELD

The present invention relates to an encoder with a new function wherein a sequential control function is added to a typical rotary encoder in such a way that an angle or a position partition is configured in a form of a software based on an absolute position data of a rotational disk of an absolute rotary encoder as compared with a conventional absolute rotary encoder which is characterized in that a conventional absolute rotary encoder is configured with a simple hardware to detect an ON/OFF signal and a square wave using the output of a optical sensor which reacts one to one after a code combined with binary numbers corresponding to a partition angle is designed on a rotation circular plate.

Namely, the present invention relates to a programmable absolute rotary encoder which is formed of a rotation circular plate recorded with a binary absolute position code corresponding to 360° in an absolute rotary encoder, a program configured to control positions about an address data inputted by a sensor in a form of a binary BCD code in the rotary circulate plate, and one chip micom and a control circuit which execute the program.

### BACKGROUND ART

The typical absolute rotary encoder is configured in such a way that a simple switching circuit for an angle partition control is designed on a rotary disk. The angle partition control code is formed with a hardware at a rotary disk using a binary code for thereby detecting an ON/OFF signal or a square wave using a sensor.

The rotary encoder is a position sensor configured to convert into a digital form the mechanical displacement degree of a rotation direction and the position displacement degree of a rotation angle and to detect such degrees. The above rotary encoder may be categorized into a rotary encoder for detecting the position of the rotation direction and a linear scale for measuring a straight line displacement.

When the encoder is categorized based on its operation principle, the encoder may be categorized into a photoelectric encoder, a magnetic encoder, an electromagnetic encoder, an electrostatic encoder, etc. The above encoder may be widely applied to machine tools or a numerical control machine tool (CNC).

The photo-detection method of the encoder may be divided into an absolute type and an incremental type.

The incremental type is characterized in that a pulse is outputted in proportion to a rotation angle of a rotary shaft; however since the signal is not individually identified, it needs to count and accumulate the number of pulses from the positions in order to recognize the revolutions with respect to the input signal. In the incremental type, it is possible to endlessly measure the revolutions from the reference point by allocating the reference positions to the scale of the rotary disk; however in this type, it must need to inconveniently set the reference point again when resupplying the electric power after the electric power was shut off.

The absolute type is characterized in that a natural position signal corresponding to the displacement of a rotary disk is outputted in a digital mode by allocating the absolute position value based on the rotation angle to the rotary disk, so the absolute type is used for the detection of rotation angle. Even when electric power is shut off, the position data is stored in the rotary disk, so the position data may be directly detected without setting the starting point.

FIG. 6 is a view illustrating a rotary disk of a typical rotary encoder, wherein the typical rotary encoder is formed with a hardware.

FIG. 2 is a view illustrating a basic structure of a rotary encoder.

Referring to FIG. 2, the basic structure of the rotary encoder includes a rotary shaft, a bearing 101 for supporting the rotary shaft, a body 111 for fixing the rotary shaft, a rotary disk 151 fixed at the rotary shaft, a light emitting unit 121 for irradiating light and a light receiving unit 131 for receiving the irradiated light, and an electronic circuit 141 for converting the change in the luminance of the light into a form of a digital signal.

Referring to FIG. 4, as for the operation principle of the typical rotary encoder, when the light emitting unit “D” configured to transmit signal emits light source, the rotary disk “Ba” controlling the signal is connected to the rotary shaft and rotates. At this time, as illustrated in FIG. 6, black and white patterns are allocated to the rotary disk “Ba”. The light which has transmitted the fixed slit “C” transmits the rotary disk or is shut off. The light receiving unit sensor “F” receiving the transmitted light detects the binary position data 32 and outputs a square wave 33 or an ON/OFF signal.

As illustrated in FIG. 6, the typical position control encoder includes a physical resolving power at the rotary disk. The rotary disk is generally designed with a hardware based on each resolving power. For example, if the resolving power is 6, the rotary disk with 6 position codes is designed. If the resolving power is 24, the rotary disk with 24 position codes is designed.

As described above, the absolute rotary encoder has been configured in such a way to manufacture the rotary disk with a n-number of position codes if there is a n-number the resolving powders. Here, the resolving powder means an angle which will be partitioned. If the resolving power is 8, the angle of 360° will be divided into 8 parts, so 8 position data may be outputted.

In case of the n-partitioned encoder based on the output type, there are a way of outputting a n-number of the ON/OFF switch contact points, a way of outputting a binary BCD code, and a way of outputting other binary gray codes. The rotary encoder may be categorized into a positive logic and a negative logic based on the stamping at the scale or the punched type. Since every product has different characteristics, the rotary encoders may not be compatible with each other, and the range of use is very limited, so the applicable field is narrow. Therefore, if any error occurs, it must need to purchase the product which has the same input and output systems due to the natural characteristics. If the purchase thereof is not possible, the equipment should be stopped endlessly.

In the conventional art field, any change in the resolving power is impossible because of the hardware-based design when designing the partition control codes of the rotary disk, and when it needs to manufacture a variety of products, it needs to purchase the dedicated rotary disk and control circuit for each resolving power, which results in lots of processes and facilities from the development to the production.

### DISCLOSURE OF INVENTION

### Technical Problem

Accordingly, the present invention is made in an effort to resolve the above problems. It is an object of the present invention to provide a rotary encoder which is characterized in that a resolving power may be freely configured using a micom and an absolute position data which is extracted in a combination of binary codes corresponding to 360° on a rotary disk, an applicable range is endless since a circuit may be configured using a bitwise operation for input and output, a manufacturing process may be significantly diminished since a product with a variety of resolving powders may be configured using a binary BCD address and a complier program which correspond to 360° in the course of manufacture, a user may easily use by freely configuring resolving powers using a source program, a special absolute rotary encoder may be easily manufactured using a complier, and various shapes of square waves may be outputted using a compile program.

In addition, it is another object of the present invention to provide a rotary encoder which is characterized in that a modification and conversion of a partition angle may be possible based on the in-site conditions, and a product with a variety of functions may be manufactured since the present invention may interlock with the surrounding micoms and CPU, and productivity and workability may be improved since various position signals may be produced, while providing a simplified circuit configuration.

The above-mentioned objects of the present invention are not limited thereto, and it is obvious that other objects which are not mentioned would be definitely understood from the descriptions below.

### Solution to Problem

To achieve the above objects, there is provided a position control encoding method in a position control encoding device which comprises a rotary disk for forming an absolute position data using a code combined with binary numbers by dividing 360°, a sensor for detecting a binary absolute position code of the rotary disk, a micom for receiving the absolute position code and logically partitioning and controlling the received absolute position code, and a signal amplification unit for amplifying the signal detected by the sensor, which method includes a step wherein when an absolute position data is received from the position detection device in order to detect the position, the position control encoding device logically partitions the absolute position data into a set value; and a step wherein the position control encoding device outputs a control signal based on the logically partitioned value.

The position detection device is an absolute rotary encoder configured to detect the rotation angle and the absolute rotary encoder outputs an absolute position data corresponding to any change in the length, and the position control encoding device is configured to logically partition the absolute position data with a set value.

The position detection device is an absolute linear encoder for detecting the position of the straight line scale, and the absolute linear encoder is configured to output an absolute position data in response to any change in the length, and the position control encoding device is configured to logically partition the absolute position data with a set value.

The absolute rotary encoder is configured to output a variety of digital signals formed in a combination of binary numbers.

The absolute linear encoder is configured to output a variety of digital signals formed in a combination of binary numbers.

The position control encoding device is configured to output a square wave or an ON/OFF signal.

Two or more than two position detection devices may be connected to the position control encoding device.

The position detection device may include a rotary encoder which outputs a binary gray code.

### Advantageous Effects

According to the present invention, it is possible to maximize the work efficiency since the conversions of the partition angle or position control codes are possible with the aid of the software-based resolving powders.

In addition, various functions such as the increase and decrease, correction, modification, etc. of the output signals may be obtained using the software, and various types of code plates which are hard to be configured with a hardware may be configured thanks to the configuration of a software-based code plate, and various products may be manufactured, and development time may be reduced.

In addition, it is possible to manufacture a new absolute rotary encoder and incremental rotary encoder by adding a high resolving power absolute rotary encoder which outputs a binary-combined code (36°×10ⁿ).

According to the present invention, a rotation circular plate corresponding to a sensor in a position control encoder or a pattern of a binary code plate of a straight line scale may be configured with a software using an absolute position data and a program, without configuring it with a hardware for a resolving power, and it is possible to easily configure a position control in multiple axes using an external CPU control PCB.

In addition, according to the present invention, various products may be easily manufactured since a resolving powder is configured with a software using an address count of 360° after the resolving powder is programmed using a complier in the CPU.

In addition, the applicable range is endless thanks to the use of the CPU of the micom, and the designing in both the absolute type and the incremental type is available, and it is possible to obtain various types of the output signals with the aid of the micom. The conventional absolute rotary encoder is limitedly used in a specific field since the resolving power per revolution is fixed by the absolute position value because of the simple hardware-based design wherein the resolving power is physically configured at the rotary disk. However, the present invention makes it possible to freely configure the resolving power per revolution using the address count of 360° and the micom. Since the circuit is configured using the bitwise operation for the sake of input and output, the applicable range is endless.

In addition, according to the present invention, since the product of a variety of resolving powers may be configured using a digital data formed of in a combination of binary numbers corresponding to 360° and a complier program during the manufacturing, the manufacturing process may be significantly decreased. The sequence may be controlled since the user may freely configure the resolving power using the source program.

In addition, even the special absolute rotary encoder may be easily made using the complier. Various types of outputs may be configured using the compile program.

### BRIEF DESCRIPTION OF THE DRAWINGS

FIG. 1 is a view illustrating the whole principle of the programmable absolute rotary encoder according to an exemplary embodiment of the present invention.

FIG. 2 is a view illustrating a configuration of a CPU control PCB built-in type structure and a CPU control PCB external type structure.

FIG. 3 is a view illustrating a multiple-axes position control using an external type control PCB.

FIG. 4 is a comparative diagram of an encoder configured with a hardware and an encoder configured with a software.

FIG. 5 is a view illustrating an absolute rotary encoder and an external type CPU board for a 360-partitioning position control according to an exemplary embodiment of the present invention.

FIG. 6 is a view illustrating a rotary disk of a rotary encoder wherein a control code is configured with a hardware.

FIG. 7 is a detailed view illustrating a binary absolute position code of a rotary disk of a 360-partitioning absolute rotary encoder.

FIG. 8 is a view illustrating an example where a decimal number corresponding to a binary absolute position data of a straight line scale.

### BEST MODES FOR CARRYING OUT THE INVENTION

The present invention is directed to a method for configuring an angle partition control code using a software about an absolute position data at a rotation disk of an absolute rotary encoder.

More specifically, the present invention is directed to a programmable absolute rotary encoder which includes a rotation circular plate recorded with a binary absolute position code of a 360°×10ⁿ in an absolute rotary encoder, a program configured to control every position about each address data inputted by a sensor in a form of various codes combined with binary numbers at the rotation circular plate, and one chip micom and a control circuit which are configured to execute the program.

The exemplary embodiments of the present invention will be described with reference to the accompanying drawings. When adding reference numbers to the components in each drawing, it is noted that the same reference numbers are given to the same components even though they are illustrated in other drawings. In the course of the description of the present invention, if it is judged that the descriptions about the known functions or configurations might make unclear the subject matters of the present invention, such descriptions may be omitted. In addition, throughout the specification, when a predetermined portion “includes” any component, unless otherwise stated, it should be interpreted to further include another component, not excluding the component.

The programmable absolute rotary encoder according to the present invention includes a rotary disk having a binary address code (360*10ⁿ) corresponding to 360°, a body including a n-number of optical sensors for detecting the binary address codes, a signal amplification circuit for amplifying the detected signal and a printed circuit board on which a micom CPU is mounted.

The present invention proposes a rotary encoder, and a multifunctional position control encoder programmable at a straight line encoder, wherein the multifunctional position control encoder includes a rotary disk having a binary address code corresponding to the absolute position value of the scale, a body having a n-number of optical sensors for detecting a binary address code, an amplification circuit for amplifying the detected signal, and a printed circuit board on which one chip micom CPU is mounted.

The present invention configures anew type encoder using the following two components, of which the first component is an absolute position (address) data, and the second component is one chip micom. The partition pattern is configured with a software using the above two components and is converted, and various outputs may be implemented.

First, the absolute position data represents an address value obtained based on a hardware configuration by allocating a binary absolute position code to a rotation disk or a linear scale like in the conventional encoder.

The present invention is directed to a position control encoding method in a position control encoding device which outputs a position control signal by receiving a position data, which includes a step wherein the position control encoding device logically partitions, into a set value, an absolute position data when receiving an absolute position data from the position detection device configured to detect the position, and a step wherein the position control encoding device outputs a control signal based on the logic partition value.

Here, the position detection device is an absolute rotary encoder for detecting the rotation angle, and the absolute rotary encoder outputs an absolute position data corresponding to any change in the rotation angle, and the position control encoding device may logically partition the absolute position data into a set value.

The position detection device is an absolute linear encoder for detecting the position of the straight line scale, and the absolute linear encoder outputs an absolute position data corresponding to any change in the length, and the position control encoding device may logically partition the absolute position data into a set value.

The absolute rotary encoder according to an exemplary embodiment of the present invention may output a binary BCD code. In addition, the absolute linear encoder according to an exemplary embodiment of the present invention may output a binary BCD code.

The position control encoding device may outputs a square wave or an ON/OFF signal.

In the exemplary embodiment of the present invention, two or more than two position detection devices may be connected to the position control encoding device.

The position detection device may include an incremental encoder which outputs a binary gray code.

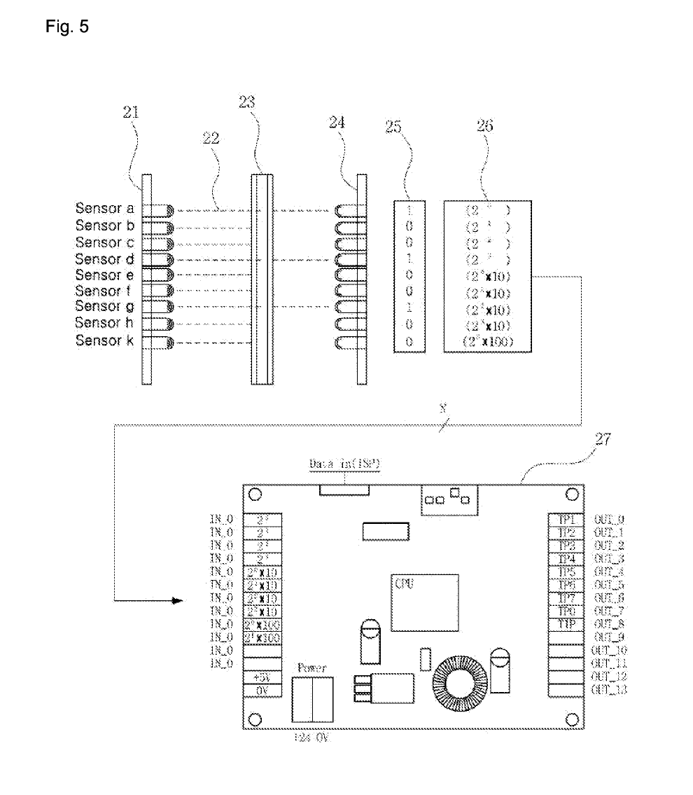

FIG. 5 is a view for describing the operation principle of the photoelectric rotary encoder.

As illustrated in FIG. 5, a light emitting sensor unit 210 outputs a light source 22, and the light which has passed through the rotary disk 23, among the light source 22 reaches the light receiving sensor 24. The light receiving sensor 24 outputs a signal of a high level when the light is detected based on an electric characteristic of the photodiode.

FIG. 5 illustrates the binary address data 25 detected by multiple light receiving sensors 24 of the absolute rotary encoder. When such data are converted into a binary BCD code and are expressed in a form of decimal numbers, the absolute position data of 73 is calculated and obtained.

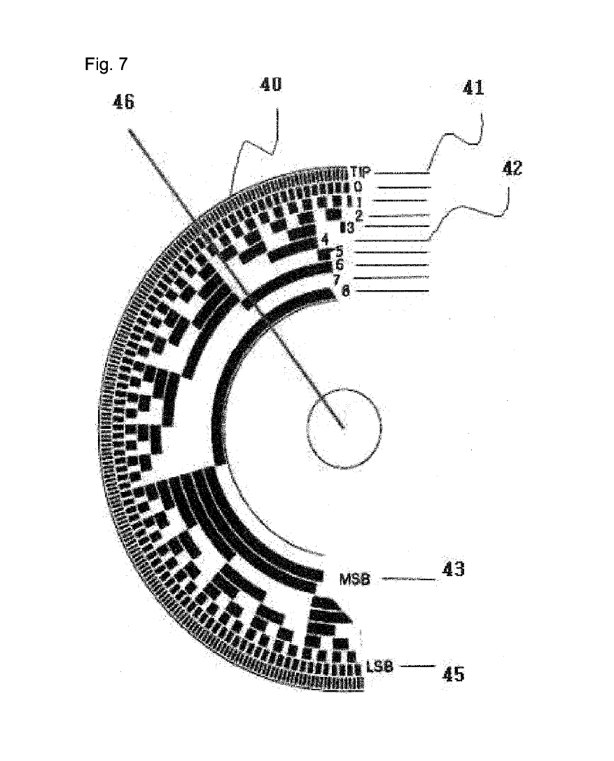

FIG. 7 is a view illustrated for easier understanding by cutting the binary address code of the 360-pulse. When the address data 46 in FIG. 7 is read, the bottom portion represents the upper most bit, so it becomes ‘1010000011’. Here, 1 of the right most side is the data representing the normal position of the TIP, it becomes ‘101000001’ from which ‘1’ is excluded. When ‘101000001’ is converted into a form of decimal numbers, it becomes ‘321’. Namely, it is known that the current position is 321 °.

According to another exemplary embodiment of the present invention, it is possible to obtain the absolute position data in another way. Namely, it is possible to control the position with the binary partition pattern formed of a software by receiving the absolute position data through the encoder which outputs the binary BCD or the binary gray code. The CPU control unit is separated for the use as an external type and then is combined with the absolute encoder which outputs the binary BCD code or the binary gray code.

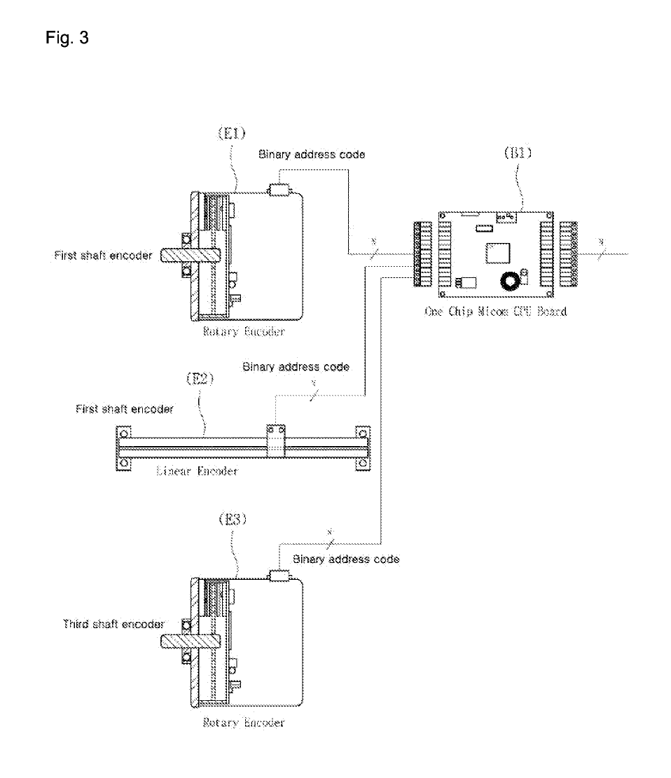

In addition, as illustrated in FIG. 3, it is possible to simply implement the position controls of multiple axes by combining with multiple absolute position encoders. For example, three encoders E1, E2 and E3 which output binary BCD are connected to the external type CPU board “B1”, and the first axis is connected to the ports “A” and “B”, and the second axis is connected to the ports “B” and “C”, and the third axis is connected to the ports “C” and “D”, and the output port is formed of “D”, “F”, and “G”, so that it may be possible to control the positions while interlocking with the three axes.

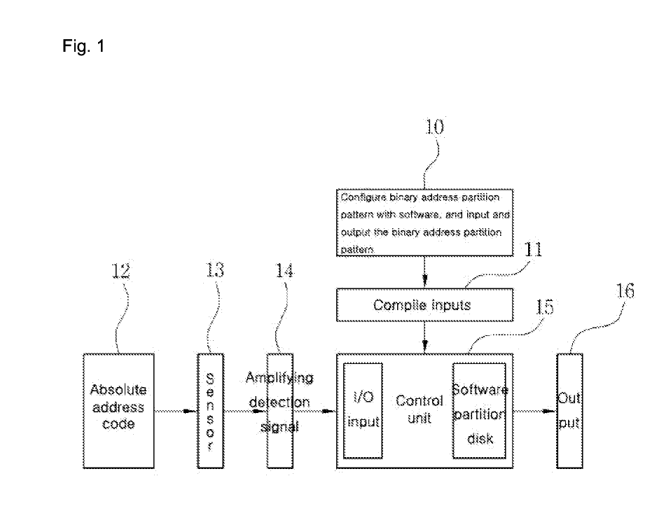

Referring to FIG. 1, the configuration and principle of the programmable multifunctional position control encoder according to the present invention will be described. The address code disk of the 360-partitioning at the absolute address code 12 is formed of a plurality of negative and positive binary codes at the rotation circular plate.

The binary code of the present invention forms a data of ‘1’ and ‘0’ at multiple sensors 13. As illustrated in FIG. 5, when the data made by each sensor are combined based on the principle when the binary code passes through the medium 22 which operates the sensor, the binary code becomes ‘1’, and when the binary code is blocked, the binary code becomes ‘0’, the binary BCD code 25 may be made.

The signal made by the sensor is amplified (14) based on the detection signal and is transferred to the input port of the micom 15 and is outputted (16) through the output port by means of the binary address partition pattern configuration with the software and the input and output (10).

The angle of 360° is partitioned into a desired number of parts based on the software-based binary address partition pattern configuration and input and output (10), and the input condition and the output condition are set and inputted into the flash memory using the compile software (11).

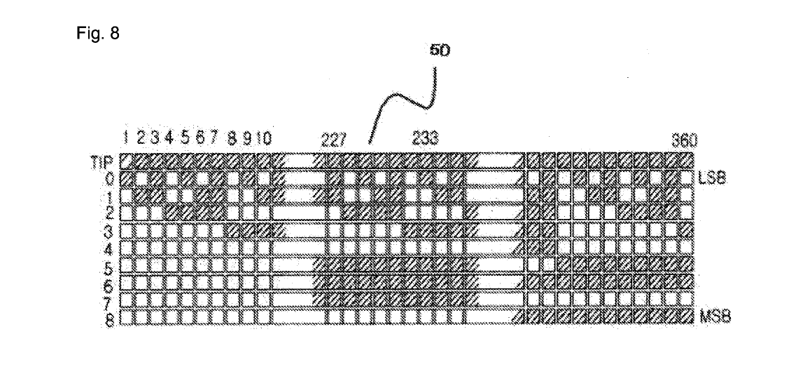

The table (50) in FIG. 8 illustrates the 360 position codes (horizontal) inputted into the CPU and multiple binary codes (vertical).

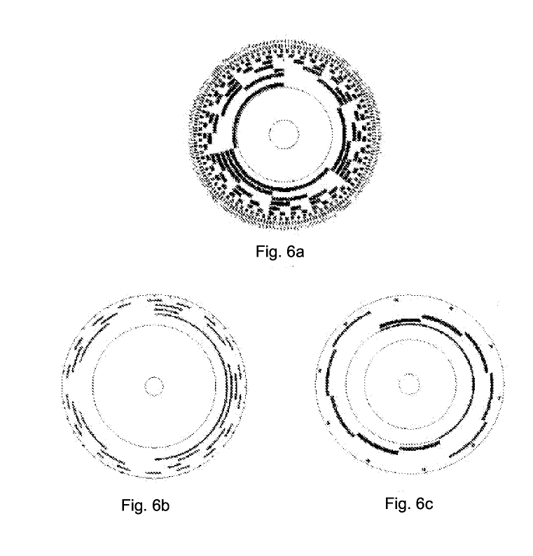

In FIG. 8, the dark black portion becomes ‘1’, and the white portion becomes ‘0’, and there are provided the binary absolute position codes to 360 in this way. The binary absolute position code, as illustrated in FIG. 6, represents the position codes formed of multiple binary data.

The table 1 shows the binary absolute position values of the 360-partitioning absolute rotary encoder and the decimal numbers corresponding to 360°.

TABLE 1
Example of when logically partitioning 360-partitioning into 8-partition

| | | | | K P | KIP |
|---|---|---|---|---|---|
| | K A | K B | K C (normal | (third | (second |
| p/n | (partition | (partition | position | normal | normal |
| (partition) | angle) | range) | value) | position) | position) |
| 1/8 | 45 | 1~45 | 22.5 | 21~24 | 18~27 |
| 2/8 | 90 | 46~90 | 47.5 | 66~69 | 63~72 |
| 3/8 | 135 | 91~135 | 72.5 | 111~114 | 108~117 |
| 4/8 | 180 | 136~180 | 97.5 | 156~159 | 153~162 |
| 5/8 | 225 | 181~225 | 122.5 | 201~204 | 198~207 |
| 6/8 | 270 | 226~270 | 147.5 | 246~249 | 243~252 |
| 7/8 | 315 | 271~315 | 172.5 | 291~294 | 288~297 |
| 8/8 | 360 | 316~360 | 197.5 | 336~339 | 333~342 |

The table 2 shows the binary absolute position values of 360°.

TABLE 2

| \ | 1° | 2° | 3° | ~ | 101° | 102° | 103° | ~ | 249° | 250° | 251° | 252° | ~ | 356° | 357° | 358° | 359° | 360° |
|---|---|---|---|---|---|---|---|---|---|---|---|---|---|---|---|---|---|---|
| TP0 | 1 | 1 | 1 | ~ | 1 | 1 | 1 | ~ | 1 | 1 | 1 | 1 | ~ | 1 | 1 | 1 | 1 | 1 |
| 2° | 1 | 0 | 1 | ~ | 1 | 1 | 1 | ~ | 1 | 0 | 1 | 0 | ~ | 0 | 1 | 0 | 1 | 0 |
| 2¹ | 0 | 1 | 1 | ~ | 0 | 1 | 1 | ~ | 0 | 1 | 1 | 0 | ~ | 0 | 0 | 1 | 1 | 0 |
| 2² | 0 | 0 | 0 | ~ | 1 | 0 | 1 | ~ | 0 | 0 | 0 | 1 | ~ | 1 | 1 | 1 | 1 | 0 |
| 2³ | 0 | 0 | 0 | ~ | 0 | 0 | 0 | ~ | 1 | 1 | 1 | 1 | ~ | 0 | 0 | 0 | 0 | 1 |
| 2° × 10 | 0 | 0 | 0 | ~ | 0 | 0 | 0 | ~ | 1 | 1 | 1 | 1 | ~ | 0 | 0 | 0 | 0 | 0 |
| 2¹ × 10 | 0 | 0 | 0 | ~ | 1 | 1 | 1 | ~ | 1 | 1 | 1 | 1 | ~ | 1 | 1 | 1 | 1 | 1 |
| 2² × 10 | 0 | 0 | 0 | ~ | 1 | 1 | 1 | ~ | 1 | 1 | 1 | 1 | ~ | 1 | 1 | 1 | 1 | 1 |
| 2³ × 10 | 0 | 0 | 0 | ~ | 0 | 0 | 0 | ~ | 1 | 1 | 1 | 1 | ~ | 0 | 0 | 0 | 0 | 0 |
| 2° × 100 | 0 | 0 | 0 | ~ | 0 | 0 | 0 | ~ | 0 | 0 | 0 | 0 | ~ | 1 | 1 | 1 | 1 | 1 |

The table 3 shows the binary absolute position values of 3600°.

TABLE 3

| \ | 1° | 2° | ~ | 1011° | 1012° | 1013° | ~ | 2419° | 2420° | 2421° | 2422° | ~ | 3598° | 3599° | 3600° |
|---|---|---|---|---|---|---|---|---|---|---|---|---|---|---|---|
| TP0 | 1 | 1 | ~ | 1 | 1 | 1 | ~ | 1 | 1 | 1 | 1 | ~ | 1 | 1 | 1 |
| 2° | 1 | 0 | ~ | 1 | 0 | 1 | ~ | 1 | 0 | 1 | 0 | ~ | 0 | 1 | 0 |
| 2¹ | 0 | 1 | ~ | 1 | 0 | 0 | ~ | 1 | 0 | 0 | 1 | ~ | 1 | 1 | 0 |
| 2² | 0 | 0 | ~ | 0 | 1 | 1 | ~ | 0 | 1 | 1 | 1 | ~ | 1 | 1 | 0 |
| 2³ | 0 | 0 | ~ | 0 | 0 | 0 | ~ | 0 | 0 | 0 | 0 | ~ | 1 | 1 | 0 |
| 2° × 10 | 0 | 0 | ~ | 1 | 1 | 1 | ~ | 1 | 1 | 1 | 1 | ~ | 0 | 0 | 1 |
| 2¹ × 10 | 0 | 0 | ~ | 1 | 1 | 1 | ~ | 1 | 1 | 1 | 1 | ~ | 0 | 0 | 0 |
| 2² × 10 | 0 | 0 | ~ | 1 | 1 | 1 | ~ | 1 | 1 | 1 | 1 | ~ | 0 | 0 | 0 |
| 2³ × 10 | 0 | 0 | ~ | 1 | 1 | 1 | ~ | 0 | 0 | 0 | 0 | ~ | 0 | 0 | 0 |
| 2° × 100 | 0 | 0 | ~ | 1 | 1 | 1 | ~ | 1 | 1 | 1 | 1 | ~ | 0 | 0 | 0 |
| 2¹ × 100 | 0 | 0 | ~ | 1 | 1 | 1 | ~ | 0 | 0 | 0 | 0 | ~ | 1 | 1 | 1 |
| 2² × 100 | 0 | 0 | ~ | 0 | 0 | 0 | ~ | 0 | 0 | 0 | 0 | ~ | 1 | 1 | 1 |
| 2³ × 100 | 0 | 0 | ~ | 0 | 0 | 0 | ~ | 1 | 1 | 1 | 1 | ~ | 1 | 1 | 1 |

The table 4 shows the binary absolute position values of 36000°.

TABLE 4

| \ | 1° | 2° | ~ | 1031° | 1032° | ~ | 23250° | 23251° | 23252° | ~ | 35998° | 35999° | 36000° |
|---|---|---|---|---|---|---|---|---|---|---|---|---|---|
| TP0 | 1 | 1 | ~ | 1 | 1 | ~ | 1 | 1 | 1 | ~ | 1 | 1 | 1 |
| 2° | 1 | 0 | ~ | 1 | 0 | ~ | 0 | 1 | 0 | ~ | 0 | 1 | 0 |
| 2¹ | 0 | 1 | ~ | 1 | 0 | ~ | 1 | 1 | 0 | ~ | 1 | 1 | 0 |
| 2² | 0 | 0 | ~ | 1 | 0 | ~ | 0 | 0 | 1 | ~ | 1 | 1 | 0 |
| 2³ | 0 | 0 | ~ | 0 | 1 | ~ | 0 | 0 | 0 | ~ | 1 | 1 | 0 |
| 2° × 10 | 0 | 0 | ~ | 0 | 0 | ~ | 1 | 1 | 1 | ~ | 1 | 1 | 0 |
| 2¹ × 10 | 0 | 0 | ~ | 0 | 0 | ~ | 0 | 0 | 0 | ~ | 0 | 0 | 1 |
| 2² × 10 | 0 | 0 | ~ | 0 | 0 | ~ | 1 | 1 | 1 | ~ | 0 | 0 | 0 |
| 2³ × 10 | 0 | 0 | ~ | 0 | 0 | ~ | 1 | 1 | 1 | ~ | 1 | 1 | 1 |
| 2° × 100 | 0 | 0 | ~ | 0 | 0 | ~ | 0 | 0 | 0 | ~ | 0 | 0 | 0 |
| 2¹ × 100 | 0 | 0 | ~ | 0 | 0 | ~ | 1 | 1 | 1 | ~ | 0 | 0 | 0 |
| 2² × 100 | 0 | 0 | ~ | 1 | 1 | ~ | 0 | 0 | 0 | ~ | 1 | 1 | 1 |
| 2³ × 100 | 0 | 0 | ~ | 0 | 0 | ~ | 1 | 1 | 1 | ~ | 1 | 1 | 1 |
| 2° × 1000 | 0 | 0 | ~ | 0 | 0 | ~ | 1 | 1 | 1 | ~ | 0 | 0 | 0 |
| 2¹ × 1000 | 0 | 0 | ~ | 0 | 0 | ~ | 0 | 0 | 0 | ~ | 0 | 0 | 0 |
| 2² × 1000 | 0 | 0 | ~ | 0 | 0 | ~ | 1 | 1 | 1 | ~ | 0 | 0 | 0 |
| 2³ × 1000 | 0 | 0 | ~ | 0 | 0 | ~ | 0 | 0 | 0 | ~ | 1 | 1 | 1 |

The table 3 shows the binary absolute position codes of 3600-partitioning, and the table 4 shows the absolute position codes of 36000-partitioning.

When 360° is partitioned by the unit of 1 °, 360 absolute position data formed of 9 bits are obtained.

The table 2 shows 360 binary absolute position data.

The position maybe controlled using a program which is characterized in that the binary absolute position data of 360° are partitioned into a predetermined range, and if the range of the predetermined partition is true, the value of ‘1’ is outputted, and if the range thereof is false, the value of ‘0’ is outputted.

More specifically, assuming that the minimal angle which is will be divided when partitioning 360° by the unit of 1° is “N”, N≦360, and the partitioning of the unit of 0.1° may be performed using 3600-pulse, and the partitioning of 0.01° may be performed using 36000-pulse, and the partitioning of 0.001° may be performed using 360000-pulse. Namely, the minimal partition angle N=1/(36°×10ⁿ).

The tables 3 and 4 show the binary absolute position data of the minimal partition angles in case of 3600° and 36000°.

Referring to FIG. 5, the light irradiated from the light emitting device 21 transmits the rotary disk and the fixed slit and reaches the light receiving device 24. Since the rotary disk and the shaft may be rotated in the fixed states, the luminance of the light irradiated onto the light receiving unit may change.

The light receiving device 24 outputs a sine wave signal in response to the change in the luminance of the light and converts the sine wave into the square wave and outputs the square wave.

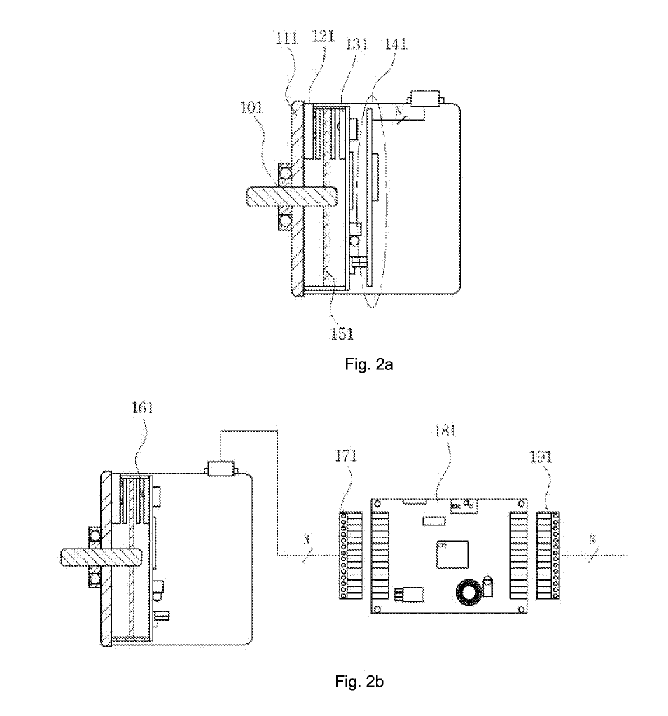

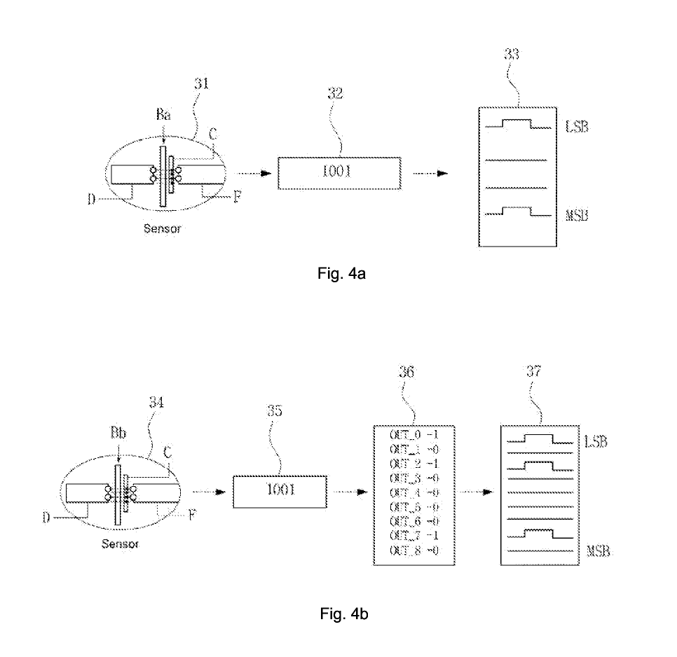

The light detection type rotary encoder is configured to output a predetermined data by receiving the position signal of ‘1’ or ‘0’ and amplifying the signal as illustrated in FIG. 2 when the signal reaches a predetermined position of the rotation circular plate since the binary address code as illustrated in FIG. 4 shuts off and transmits the light.

The part “A” of the rotary encoder in FIG. 4 is formed of “B” and “C”, “D” and “F”, and the part “D” is formed of the light emitting unit of the photo diode, and “B” is formed of the rotary disk, and “C” is formed of the scale for controlling the quantity where light transmits, and “F” is formed of the light receiving unit for receiving light.

The light which has transmitted “D” transmits the binary code of the rotary disk of “B”, and the sine wave is made using the transmitted light. Namely, if the light reaches “F”, a high signal is outputted, and if the light does not reach, a low signal is outputted.

Referring to FIG. 6, the binary absolute position code represents the position code formed of a plurality of binary data, and as illustrated in FIG. 4, the binary data becomes ‘1’ if the light transmits, and the binary data becomes ‘0’ if the light does not transmit.

The table 2 shows the binary absolute position codes of 360-partitoning.

The table 3 shows the binary absolute position codes of 3600-partitioning, and the table 4 shows the absolute position codes of 36000-partitioning.

Referring to FIG. 3, the rotary disk of the present invention will be described as an example, When the rotary shaft of the rotary encoder rotates or stops, the address data of where the optical sensor is positioned becomes ‘001001001’. When the binary code of ‘001001001’ is converted into the decimal number, the value becomes ‘73’. Therefore, it is possible to recognize that the current position at the rotary disk of 360° is 73°.

When the address data 46 in FIG. 7 is read, the bottom portion becomes the upper most bit, so the value ‘1010000011’ is obtained. Here, since ‘1’ of the right side is the position data of TIP, ‘1’ is excluded from ‘101000001’, and when the value ‘101000001’ is converted into the decimal number, ‘321’ is obtained. In other words, it is possible to recognize that the current position is 321°.

FIG. 8 is a view illustrating that the sensor detects the binary address signal.

Referring to the table 2, the rotary disk of 360-partitioning is formed of 9 binary address codes of (TPO), (2⁰), (2¹), (2²), (2³), (2°×10), (2¹×10), (2²×10), (2³×10), (2°×100), one position signal (TPO), and 10 sensors corresponding thereto.

As illustrated in FIG. 6, if it is possible to recognize the current position using the address data of 360°, the resolving power may be logically formed using the program. When 360° is partitioned into 8 parts, the data as shown in the table 1 are obtained.

In the table 1, “KA” is the value obtained by diving 360 with 8, and “KB” is the range of the partition angle, and “KC” is the normal position value of the partition angle, and “KP” and “KIP” are the position values of the normal position.

Referring to FIG. 2, the rotary disk of the 360-partioning includes binary address codes of (TPO), (2⁰), (2¹), (2²), (2³), (2°×10), (2¹×10), (2²×10), (2³×10), (2°×100), (2¹×100), (2²×100), (2³×100), (2°×1000), (2¹×1000), (2²×1000), (2³×1000), and the sensors corresponding thereto.

Referring to the table 3, the rotary disk of 3600-partitioning includes binary address codes of (TPO), (2⁰), (2¹), (2²), (2³), (2°×10), (2¹×10), (2²×10), (2³×10), (2°×100), (2¹×100), (2²×100), (2³×100), (2°×1000), (2¹×1000), (2²×1000), (2³×1000) and sensors corresponding thereto.

Referring the table 4, the rotary disk of 36000-paritioning includes the binary address code of (TPO), (2⁰), (2¹), (2²), (2³), (2°×10), (2¹×10), (2²×10), (2³×10), (2°×100), (2¹×100), (2²×100), (2³×100), (2°×1000), (2¹×1000), (2²×1000), (2³×1000) and sensors corresponding thereto.

In other words, in the rotary disk of the present invention, if (36°×10ⁿ), the rotary disk of the N-partition obtained by multiplying 10ⁿ with 36° includes a TPO (normal position binary data), a binary address code, and a n-number of sensors corresponding thereto.

The n-number of the signals detected by the sensors is converted into BCD codes which represent the absolute position data.

The position data of the rotation circular plate of the current rotary encoder represent the result values when such data are coincided with the position data programmed in the micom control unit. For example, assuming that the sections of 0°˜45° are “k1”, and “2ⁿ˜2ⁿ×10ⁿ” is “bcd1”, and

when the values are partitioned using an if-statement,

{if((bcd1>0)&&(bcd1<=45)) {OUTa=1; OUTb=1; OUTc=0}}

‘110’ is outputted.

When the position data detected by the rotary disk of the N-partitioning and the n-number of the sensors are compared with the position data programmed at the micom, the position data are coincided with each other, the ON/OFF signal or the square wave corresponding thereto are outputted.

Referring to FIG. 5, the micom receives each individual position data (accurate address data) which are converted into the binary BCD codes generated using a plurality of the sensors in the present invention, and a single or multiple form of square waves or ON/OFF signals are outputted in response to the input and output conditions formed of the software. At this time, the number of the sensors corresponding to the absolute position values is coincided with the number of the bits which form the binary address codes.

For example, when the BCD codes are received using the absolute rotary disk of 360-partitioning, the position data of 9-bit is necessary. According to the situation, when it additionally needs the position data of 2-bit for the sake of the further position detection, namely, if the position data of 11-bit are necessary, 11 sensors are necessary.

The absolute position data used in the present invention is made using the binary BCD codes, and in order to make the absolute position data of 36000-pulse, the data (table 4) of the binary BCD codes of 16 bits are necessary together with 16 sensors.

When the absolute rotary encoder having high resolving powers is configured for the sake of the precise and accurate position controls in the present invention, if multiple sensors are configured to correspond to one rotary disk, the configuration becomes complicated, so it is preferred that the rotary disks are divided into two or three in the axial directions.

In addition, it is possible to configure the software-based binary code plate using the incremental encoder if necessary. Namely, the reference original points of the incremental encoder are scanned, and the minimal unit pulse is received in a form of the binary gray code and is up-counted or down-counted, for thereby configuring the whole scale, whereby it is possible to control a single or multiple form of square waves.

FIG. 2 is a view illustrating a CPU control PCB built-in type encoder “a” and a CPU control PCB external type encoder “b” according to an exemplary embodiment of the present invention.

Referring to FIG. 2, in order to obtain in a form of the binary BCD codes the binary address data which are the absolute address necessary in the present invention, the CPU control board 141 may be mounted on the absolute rotary disk and the CPU PCB or the CPU PCB 141 may be separated and then engaged with the absolute encoder which outputs the binary BCD codes. When the absolute rotary disk or the binary position data of the straight line scale corresponds (is positioned in response to) to the logical partitioning angle which is previously programmed, the ON/OFF signals or the square waves may be outputted.

The present invention is directed to logically designing a predetermined output condition (the binary code pattern of the rotary disk, the binary code pattern of the absolute linear scale) with respect the input by using the software and is also directed to outputting the ON/OFF signal or the square waves when the straight line axis of the encoder and the rotary shaft correspond (are located in response to) to the logical partitioning position, by receiving the binary absolute position code (binary address code) corresponding to 360° or the binary BCD, binary data.

The present invention is directed to the programmable multifunctional encoder. The encoder of the present invention is characterized in that the absolute encoder receives a binary BCD code, and the incremental encoder receives a binary gray code.

Meanwhile, the position control encoding method according to an exemplary embodiment of the present invention may be implemented using a computer-readable tool on a computer-readable medium. The computer-readable medium includes all kinds of the recording devices at which the data are stored and read by the computer system.

For example, the computer-readable medium is ROM, RAM, CD-ROM, a magnetic tape, a hard disk, a floppy disk, a portable storage, a nonvolatile memory (flash memory), an optical data storage, etc. In addition, the computer-readable medium may be implemented in a form of carrier wave (for example, a transmission through the internet).

In addition, the computer-readable recording medium may be a code which is distributable over the computer systems connected through the computer communication network and is readable in a distribution way, so the computer-readable recording medium may be stored in a form of codes and may be executed.

The present invention has been described so far with some exemplar embodiments, but such exemplary embodiments are provided for illustrative purposes, not limiting the disclosure. It is obvious that a person having ordinary skill in the art may change and modify in various ways without departing from the concept of the present invention and the scope of the rights recited in the claims.

Legend of Reference Numbers

| | |
|---|---|
| 101: bearing | 111: body |
| 151: rotary disk | 121: light emitting unit |
| 131: light receiving unit | 141: electronic circuit |

1. A position control encoding method in a position control encoding device which comprises a rotary disk for forming an absolute position data of 360°, a sensor for detecting an absolute position code of the rotary disk, a micom for receiving the absolute position code and logically partitioning and controlling the received absolute position code, and a signal amplification unit for amplifying the signal detected by the sensor, comprising:
a step wherein when an absolute position data is received from the position detection device in order to detect the position, the position control encoding device logically partitions the absolute position data into a set value; and
a step wherein the position control encoding device outputs a control signal based on the logically partitioned value,
wherein the position detection device is an absolute linear encoder configured to detect the position of a straight line scale, and the absolute linear encoder outputs an absolute position data corresponding to any change in the length, and the position control encoding device is configured to logically partition the absolute position data with a set value.

2. The method of claim 1, wherein the absolute linear encoder is configured to output a digital code formed in a combination of binary numbers.

3. The method of claim 1, wherein the position control encoding device is configured to output a square wave or an ON/OFF signal.

4. The method of claim 1, wherein two or more than two position detection devices are connected to the position control encoding device.

5. The method of claim 1, wherein the rotary disk is formed of a digital code formed in a combination of binary numbers.

6. The method of claim 1, wherein the rotary disk is an incremental type having a reference original point and is configured to form the absolute position data by counting after the original point is detected.

7. The method of claim 1, wherein the position detection device is an incremental type having a reference original point and is configured to form an absolute position data by counting after the original point is detected.

8. A computer-readable recording medium which comprises a program based on which a computer executes a method of claim 1.

9. A computer-readable recording medium which comprises a program based on which a computer executes a method of claim 2.

10. A computer-readable recording medium which comprises a program based on which a computer executes a method of claim 3.

11. A computer-readable recording medium which comprises a program based on which a computer executes a method of claim 4.

12. A computer-readable recording medium which comprises a program based on which a computer executes a method of claim 5.

13. A computer-readable recording medium which comprises a program based on which a computer executes a method of claim 6.

14. A computer-readable recording medium which comprises a program based on which a computer executes a method of claim 7.
